(19) United States
(12) Patent Application Publication
(10) Pub. No.: US 2025/0345831 A1
(43) Pub. Date: Nov. 13, 2025

(54) SUBSTRATE TREATING APPARATUS

(71) Applicant: SEMES CO., LTD., Cheonan-si (KR)

(72) Inventors: Byung Woo SIM, Seoul (KR); Bok Kyu LEE, Cheonan-si (KR)

(73) Assignee: SEMES CO., LTD., Cheonan-si (KR)

(21) Appl. No.: 19/203,393

(22) Filed: May 9, 2025

(30) Foreign Application Priority Data
May 10, 2024 (KR) 10-2024-0061958

(51) Int. Cl. B08B 9/032; B08B 3/08; B08B 15/02; H01L 21/67

(52) U.S. Cl. CPC B08B 9/0325; B08B 3/08; B08B 9/0323; B08B 9/0327; B08B 15/02; B08B 2209/032; H01L 21/67017

(57) ABSTRACT

Provided is an apparatus for treating a substrate. The apparatus includes an exhaust unit for exhausting gas in a treatment space of a liquid treatment chamber. The exhaust unit includes: an exhaust pipe connected to the liquid treatment chamber and having an exhaust passage through which gas exhausted from the treatment space flows; a cleaning solution supply unit provided in the exhaust pipe and supplying a cleaning solution to the gas flowing through the exhaust passage; and a cleaning solution outlet pipe connected to the exhaust pipe and through which the cleaning solution supplied to the exhaust passage is discharged.

### CROSS-REFERENCE TO RELATED APPLICATIONS

This application claims priority to and the benefit of Korean Patent Application No. 10-2024-0061958 filed in the Korean Intellectual Prope Office on May 10, 2024, the entire contents of which are incorporated herein by reference.

### TECHNICAL FIELD

The present invention relates to a substrate treating apparatus, and more particularly to a substrate treating apparatus for liquid treating a substrate disposed within a treatment space while exhausting the treatment space.

### BACKGROUND ART

To manufacture semiconductor devices or liquid crystal displays, various processes, such as photography, etching, ashing, ion implantation, thin film deposition, and cleaning, are performed on substrates. Among them, in the photography, etching, ashing, and cleaning processes, a liquid treating process supplying a liquid onto the substrate is performed. In the process of treating the substrate by supplying a liquid in a liquid treatment chamber, a gaseous treatment solution and a large amount of fume are generated. The exhaust gas and fume are exhausted to the outside through an exhaust unit.

When fume is exhausted through the exhaust pipe, a large amount of fume deposition in the exhaust pipe may narrow the exhaust passage of the exhaust pipe, which reduces the exhaust efficiency. In addition, the narrowing of the exhaust passage due to the deposition of fume may cause a hunting phenomenon that increases the pressure in the exhaust pipe, which may cause process failure.

In particular, in the case of a structure in which each individual exhaust pipe connected to each of a plurality of process chambers is connected to a collective exhaust pipe, the foregoing problems are exacerbated because the fumes discharged from each process chamber flow through the collective exhaust pipe.

### SUMMARY OF THE INVENTION

The present invention has been made in an effort to provide a substrate treating apparatus that improves substrate treatment efficiency during a substrate treatment process.

The present invention has also been made in an effort to provide a substrate treating apparatus that prevents fumes generated during a substrate treatment process from being deposited in an exhaust pipe.

The present invention has also been made in an effort to provide a substrate treating apparatus that prevents fumes generated during a substrate treatment process from being deposited in an exhaust pipe, thereby preventing exhaust efficiency.

The objectives of the present disclosure are not limited thereto and other objectives not stated herein may be clearly understood by those skilled in the art from the following description.

An exemplary embodiment of the present invention, an apparatus for treating a substrate, the apparatus comprising: a liquid treatment chamber having a treatment space and supplying a treatment solution to a substrate disposed in the treatment space to liquid treat the substrate; and an exhaust unit for exhausting gas in the treatment space, wherein the exhaust unit includes: an exhaust pipe connected to the liquid treatment chamber, and having a first exhaust passage through which gas exhausted from the treatment space flows; a first cleaning solution supply unit provided in the exhaust pipe to supply a cleaning solution to the gas flowing through the first exhaust passage; and a first cleaning solution discharge pipe connected to the exhaust pipe to discharge the cleaning solution supplied to the first exhaust passage.

According to the exemplary embodiment of the present invention, the first cleaning solution supply unit may include a first cleaning nozzle that sprays a cleaning solution.

According to the exemplary embodiment of the present invention, the first cleaning nozzle may be provided to spray a cleaning solution in a direction towards the first cleaning solution discharge pipe.

According to the exemplary embodiment of the present invention, an inlet of the first cleaning solution discharge pipe and the first cleaning nozzle may be provide to be opposed to each other in an upward and downward direction.

According to the exemplary embodiment of the present invention, the first cleaning nozzle may be provided to spray a cleaning solution in the form of mist.

According to the exemplary embodiment of the present invention, the first cleaning nozzle further may include, a body; a cleaning solution flow path provided in the body and discharging a cleaning solution; and a gas flow path formed in the body, and supplying gas towards the cleaning solution discharged from the cleaning solution flow path to make the cleaning solution be in the form of mist.

According to the exemplary embodiment of the present invention, the first cleaning solution supply unit further includes a controller controlling the first cleaning nozzle, and the controller may controls the first cleaning solution supply unit to cause the first cleaning nozzle to discharge a cleaning solution at a set interval.

According to the exemplary embodiment of the present invention, the first cleaning solution supply unit further includes a controller controlling the first cleaning nozzle, and the controller may controls the cleaning solution supply unit to cause the first cleaning nozzle to spray a cleaning solution when an interlock occurs in the substrate treating apparatus due to an abnormality in the exhaust unit.

According to the exemplary embodiment of the present invention, the first cleaning solution supply unit further includes a controller controlling the first cleaning nozzle, and the controller may controls the first cleaning solution supply unit such that the amount of discharge of the gas is varied based on the amount of fume contained in the gas being exhausted through the first exhaust passage.

According to the exemplary embodiment of the present invention, the controller may controls the first cleaning solution supply unit such that when the amount of fume contained in the exhausted gas increases, the amount of gas supplied to the first cleaning nozzle is increased.

According to the exemplary embodiment of the present invention, the first cleaning solution discharge pipe includes: a liquid inlet portion including an inlet of the first cleaning solution discharge pipe; and a discharge pipe portion extending from an end of the liquid inlet portion and having a passage area constant along a longitudinal direction thereof, and an area of the inlet of the first cleaning solution discharge pipe may be provide to be larger than an area of a passage of the discharge pipe portion.

According to the exemplary embodiment of the present invention, the liquid inlet portion may be provided to have a cross-sectional area gradually increasing from the discharge pipe portion in a direction towards the inlet of the first cleaning solution discharge pipe.

According to the exemplary embodiment of the present invention, the discharge pipe portion is disposed below the exhaust pipe and parallel to the exhaust pipe, and the liquid inlet portion is inclined upwardly from an end of the discharge pipe portion in an opposite direction of the exhaust pipe portion and may connect to the exhaust pipe.

An exemplary embodiment of the present invention, an apparatus for treating a substrate, the apparatus comprising: a plurality of liquid treatment chambers having a treatment space, and supplying a treatment solution to a substrate located in the treatment space to liquid treat the substrate; and an exhaust unit for exhausting gas from the treatment space of each of the plurality of liquid treatment chambers, wherein the exhaust unit includes: a plurality of first individual exhaust pipes connected to the plurality of corresponding liquid treatment chambers, respectively; a first collective exhaust pipe to which the plurality of first individual exhaust pipes is connected and through which gas exhausted through each of the plurality of first individual exhaust pipes flows; a first cleaning solution supply unit provided in the first collective exhaust pipe to supply a cleaning solution to the gas flowing through the first collective exhaust pipe; and a first cleaning solution discharge pipe connected to the first collective exhaust pipe to discharge a cleaning solution supplied to the first collective exhaust pipe.

According to the exemplary embodiment of the present invention, each of the plurality of liquid treatment chambers includes: a first nozzle for supplying a treatment solution of a first component; and a second nozzle for supplying a treatment solution of a second component, and the exhaust unit includes: a plurality of second individual exhaust pipes connected to the plurality of corresponding liquid treatment chambers, respectively; a second collective exhaust pipe to which the plurality of second individual exhaust pipes is connected and through which gas exhausted through each of the plurality of secondary individual exhaust pipes flows; a second cleaning solution supply unit may provide in the second collective exhaust pipe to supply a cleaning solution to the gas flowing through the second collective exhaust pipe; and a second cleaning solution discharge pipe connected to the second collective exhaust pipe to discharge a cleaning solution supplied to the second collective exhaust pipe.

According to the exemplary embodiment of the present invention, the first cleaning solution supply unit includes a first cleaning nozzle for spraying a cleaning solution to gas flowing through the first collective exhaust pipe, and the first cleaning nozzle may provide to spray a cleaning solution in a direction towards the first cleaning solution discharge pipe.

According to the exemplary embodiment of the present invention, an inlet of the first cleaning solution discharge pipe and the first cleaning nozzle may provide to be opposed to each other in an upward and downward direction.

According to the exemplary embodiment of the present invention, the first cleaning nozzle and the second cleaning nozzle are provided to spray a cleaning solution in the form of mist, and the first cleaning nozzle further may include, a body; a cleaning solution flow path provided in the body and discharging a cleaning solution; and a gas flow path for supplying gas toward the cleaning solution discharged from the cleaning solution flow path to make the cleaning solution be in the form of mist.

According to the exemplary embodiment of the present invention, the first cleaning solution discharge pipe includes: a liquid inlet portion including an inlet of the first cleaning solution discharge pipe; and a discharge pipe portion extending from the liquid inlet portion and having a passage area constant along a longitudinal direction thereof, an area of the inlet of the first cleaning solution discharge pipe is provided larger than an area of a passage of the discharge pipe portion, and the liquid inlet portion may be provide to have a cross-sectional area gradually expanding from the discharge pipe portion in a direction toward the inlet of the first cleaning solution discharge pipe.

An exemplary embodiment of the present invention, an apparatus for treating a substrate, the apparatus comprising: a plurality of liquid treatment chambers having a treatment space and supplying a treatment solution to a substrate located in the treatment space to liquid treat the substrate; and an exhaust unit for exhausting gas from the treatment space of each of the plurality of liquid treatment chambers, each of the plurality of liquid treatment chambers includes: a first nozzle for supplying a treatment solution of a first component; and a second nozzle for supplying a treatment solution of a second component, and the exhaust unit includes: a plurality of first individual exhaust pipes connected to the plurality of corresponding liquid treatment chambers, respectively; a plurality of second individual exhaust pipes connected to the liquid treatment chambers, respectively, at a position facing the plurality of first individual exhaust pipes when viewed from the top; a first collective exhaust pipe to which the plurality of first individual exhaust pipes is connected and through which gas exhausted through each of the plurality of first individual exhaust pipes flows; a second collective exhaust pipe to which the plurality of second individual exhaust pipes is connected and through which gas exhausted through each of the plurality of secondary individual exhaust pipes flows; a first cleaning solution supply unit provided in the first collective exhaust pipe to supply a cleaning solution to the gas flowing through the first collective exhaust pipe; and a first cleaning solution discharge pipe connected to the first collective exhaust pipe to discharge the cleaning solution supplied to the first collective exhaust pipe, the first cleaning solution supply unit includes a first cleaning nozzle for spraying a cleaning solution to gas flowing through the first collective exhaust pipe in the form of mist, an inlet of the first cleaning solution discharge pipe and the first cleaning nozzle are provided to face each other in an upward and downward direction, the first cleaning solution discharge pipe includes: a liquid inlet portion including an inlet of the first cleaning solution discharge pipe; and a discharge pipe portion extending from the liquid inlet portion and having a passage area constant along a longitudinal direction thereof, and an area of the inlet of the first cleaning solution discharge pipe may be provide larger than the passage area of the discharge pipe portion.

According to the exemplary embodiment of the present invention, fumes generated during the substrate treatment process may be prevented from being deposited in the exhaust pipe.

Furthermore, according to the exemplary embodiment of the present invention, it is possible to prevent the problem in that fume is deposited in the exhaust pipe to reduce exhaust efficiency.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating an exemplary embodiment of a substrate treating apparatus of the present invention.

FIG. 2 is a cross-sectional view schematically illustrating an exemplary embodiment of a liquid treatment chamber of FIG. 1.

FIG. 3 is a diagram schematically illustrating a structure of an exhaust unit connected to the liquid treatment chamber of the present invention.

FIG. 4 is a cross-sectional view illustrating one example of a cleaning nozzle of FIG. 3.

FIG. 5 is a diagram schematically illustrating the flow of exhaust gas, cleaning solution, and fume within the exhaust unit.

FIG. 6 is a cross-sectional view illustrating another exemplary embodiment of the exhaust unit of FIG. 3.

FIGS. 7 to 9 are diagrams schematically illustrating other examples of the substrate treating apparatus of FIG. 1.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

The exemplary embodiment of the present invention may be modified in various forms, and the scope of the present invention should not be construed as being limited to the following exemplary embodiments. The present exemplary embodiment is provided to more completely explain the present invention to those skilled in the art. Therefore, the shapes of elements in the drawings are exaggerated to emphasize clearer descriptions.

In the present invention, a substrate is described by way of example as a wafer used in the manufacture of semiconductors. Alternatively, however, the substrate may be a mask or a flat display panel.

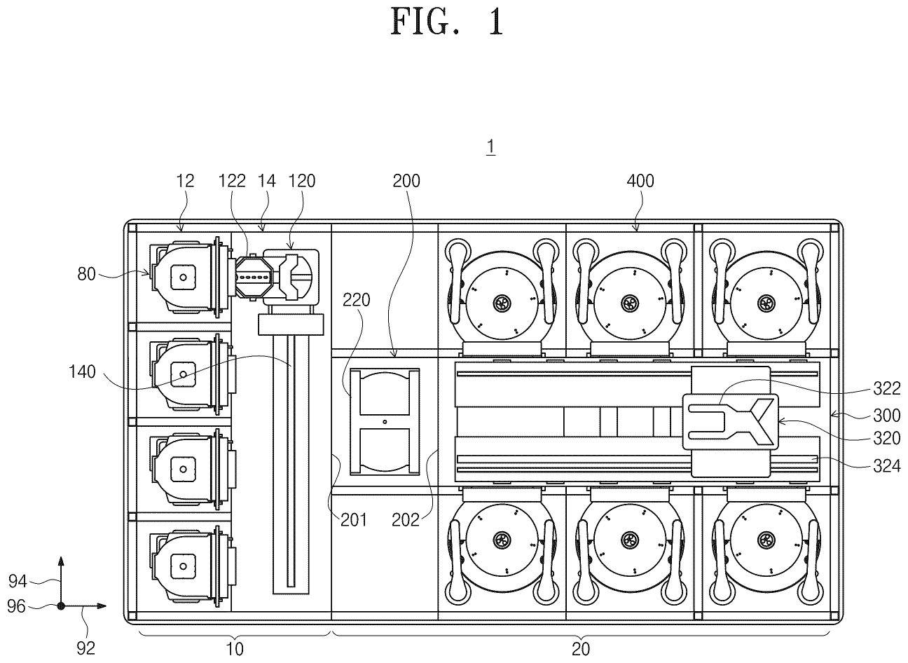

FIG. 1 is a top plan view schematically illustrating a substrate treating apparatus according to an exemplary embodiment of the present invention.

Referring to FIG. 1, a substrate treating apparatus includes an index module 10, and a treating module 20. According to the exemplary embodiment, the index module 10 and the treating module 20 are disposed in one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

An index robot 120 is provided to the index frame 14. Within the index frame 14, a guide rail 140 is provided with a longitudinal direction thereof in the second direction 94, and the index robot 120 may be movably provided along the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The treating module 20 includes a buffer unit 200, a transfer chamber 300, a liquid treatment chamber 400, an exhaust unit 1500, and a controller 2.

The buffer unit 200 provides a space in which the substrate W loaded into the treating module 20 and the substrate W unloaded from the treating module 20 stay temporarily. The liquid treatment chamber 400 performs a liquid treating process of treating the substrate W with a liquid by supplying a liquid onto the substrate W. The transfer chamber 300 transfers the substrate W between the buffer unit 200 and the liquid treatment chamber 400.

The transfer chamber 300 may be provided so that a longitudinal direction is the first direction 92. The buffer unit 200 may be disposed between the index module 10 and the transfer chamber 300. A plurality of liquid treatment chambers 400 is provided and may be disposed on the side of the transfer chamber 300. The liquid treatment chamber 400 and the transfer chamber 300 may be disposed in the second direction 94. The buffer unit 200 may be located at one end of the transfer chamber 300.

According to the example, the liquid treatment chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96. The liquid treatment chamber may be provided in plurality stacked in the third direction.

The transfer chamber 300 includes a transfer robot 320. Within the transfer chamber 300, a guide rail 340 is provided with a longitudinal direction thereof in the first direction 92, and the transfer robot 320 may be movably provided along the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forwardly and backwardly.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit is the face facing the index module 10, and the back face 202 of the buffer unit is the face facing the transfer chamber 300. The index robot 120 may access into the buffer unit 200 through the front face 201 of the buffer unit, and the transfer robot 320 may access into the buffer unit 200 through the rear face 202 of the buffer unit.

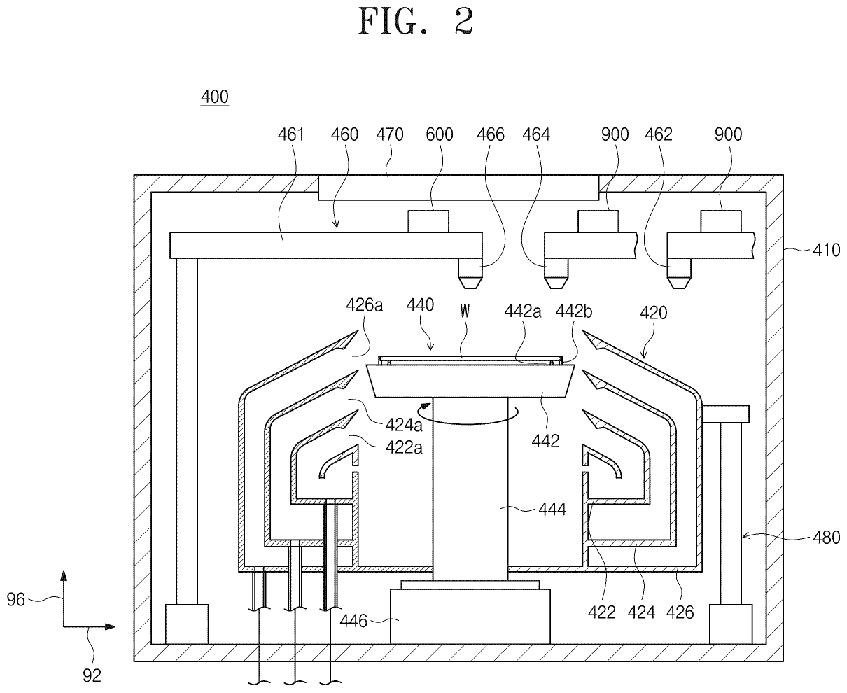

FIG. 2 is a diagram schematically illustrating an exemplary embodiment of the liquid treatment chamber of FIG. 1.

Referring to FIG. 2, the liquid treatment chamber includes a housing 410, a cup 420, a support unit 440, a nozzle unit 460, and a lifting unit 480.

The housing 410 is provided in a generally rectangular parallelepiped shape. The cup 420, the support unit 440, and the nozzle unit 460 are disposed within the housing 410. A fan filter unit 470 is disposed on the upper wall of the housing 410.

The fan filter unit 470 generates a downward airflow in the interior of the housing 410. The fan filter unit 470 may have a filter and a fan. The fan introduces outside air into the treatment space, and the filter removes particles that remain in the outside air. The downward airflow introduced by the fan-filter unit 470 provides a uniform airflow over the top of the substrate. As the surface of the substrate W is treated, fumes generated from the treatment solution are exhausted to the outside of the treatment space 402 through the exhaust unit 1500 along with the gas introduced into the treatment space 402.

The cup 420 has a treatment space 402 with an open top. The cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. When the liquid treatment process is in progress, the treatment solution scattered by the rotation of the substrate W is introduced into the recovery space through inlets 422a, 424a, and 426a of the respective recovery containers 422, 424, and 426. According to the exemplary embodiment, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 supports the substrate W in the treatment space. The support unit 440 includes a support plate 442 and a driving shaft 444. An upper surface of the support plate 442 may be provided in a generally circular shape, and may have a diameter larger than a diameter of the substrate W. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. Further, the support plate is provided with a support pin 442a that supports the rear surface of the substrate W, and the support pin 442a has an upper end protruding from the support plate 442 such that the substrate W is spaced apart from the support plate 442 by a certain distance. The support pin 442a is disposed closer to the center of the support plate 442 than the chuck pin 442b. A drive shaft 444 is driven by a driver 446, is connected to the center of the bottom surface of the substrate W, and rotates the support plate 442 with respect to the central axis thereof.

The nozzle unit 460 supplies a liquid onto the substrate W supported on the support unit 440. The liquid may be provided in a plurality of types, and may be sequentially supplied onto the substrate W. The nozzle unit 460 includes a first nozzle 462, a second nozzle 464, and a third nozzle 466. The first nozzle 462 supplies a treatment solution of a first component onto the substrate W. The treatment solution of the first component may be a solution that removes any residual film or foreign substances remaining on the substrate W. For example, the treatment solution of the first component may be an acid-based chemical, such as sulfuric acid, hydrofluoric acid, phosphoric acid, or hydrochloric acid, an alkaline-based chemical, such as ammonia, or a mixture of acid and alkaline-based chemicals. The second nozzle supplies a treatment solution of a second component to the substrate W. For example, the treatment solution of the second component may be an organic solvent. The organic solvent may be isopropyl alcohol (IPA). The third nozzle supplies a treatment solution of a third component onto the substrate W. For example, the treatment solution of the third component may be water. The first nozzle 462, the second nozzle 464, and the third nozzle 466 are supported by different arms 461, which may be independently movable. Optionally, the first nozzle 462, the second nozzle 464, and the third nozzle 466 may be mounted on the same arm 461 and moved simultaneously.

The lifting unit 480 adjusts a relative height between the cup 420 and the support unit 440. In one example, the lifting unit 480 moves the cup 420 in an upward and downward direction. By the up and down movement of the cup 420, a relative height between the cup 420 and the substrate W is changed. Through this, the recovery containers 422, 424, and 426 to which pre-treatment solutions are recovered are changed according to the type of liquid supplied to the substrate W, so that it is possible to separate and recover the liquids. Unlike the description, the cup 420 may be fixedly installed, and the lifting unit 480 may move the support unit 440 in the vertical direction.

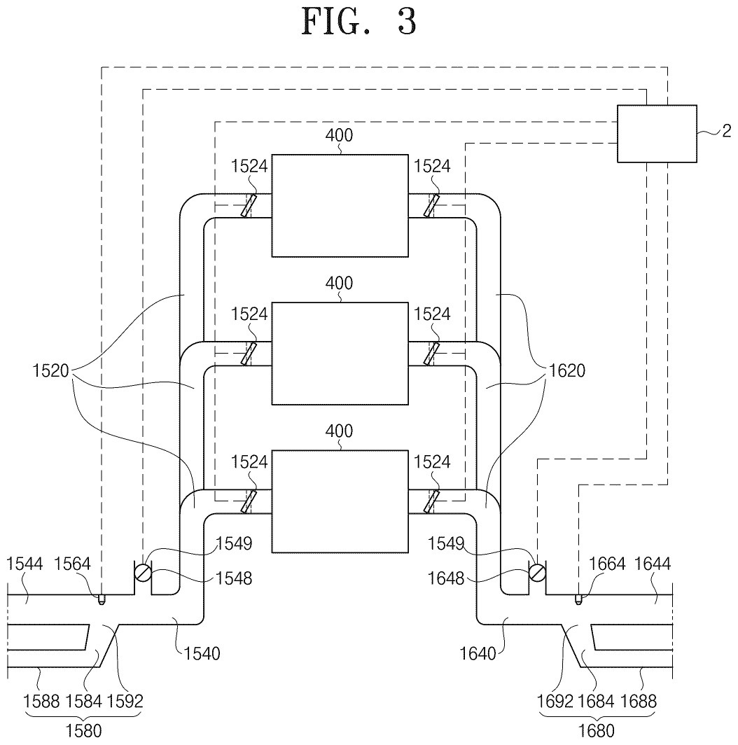

FIG. 3 is a diagram schematically illustrating a configuration of the exhaust unit connected to the plurality of liquid treatment chambers of the present invention.

The exhaust unit 1500 exhausts gas within the treatment space 402 of the liquid treatment chamber 400. Referring to FIG. 3, the exhaust unit 1500 includes a first individual exhaust pipe 1520, a first collective exhaust pipe 1540, a first cleaning solution discharge pipe 1580, a first cleaning solution supply unit 1560, a second individual exhaust pipe 1620, a second collective exhaust pipe 1640, a second cleaning solution discharge pipe 1680, and a second cleaning solution supply unit 1660.

The liquid treatment chambers 400 are connected to the first individual exhaust pipe 1520 and the second individual exhaust pipe 1620, respectively.

The plurality of first individual exhaust pipes 1520 is connected to the first collective exhaust pipe 1540. The plurality of second individual exhaust pipes 1620 is connected to the second collective exhaust pipe 1640. The first cleaning solution supply unit 1560 is provided in the first collective exhaust pipe 1540, and the first cleaning solution discharge pipe 1580 is connected to the first collective exhaust pipe 1540. The second cleaning solution supply unit 1660 is provided in the second collective exhaust pipe 1640, and the second cleaning solution discharge pipe 1680 is connected to the second collective exhaust pipe 1640.

The configuration, coupling relationship, and operation of each of the plurality of first individual exhaust pipes 1520, the first collective exhaust pipes 1540, the first cleaning solution supply unit 1560, and the first cleaning solution discharge pipe 1580 are the same or similar to the configuration, coupling relationship, and operation of each of the plurality of second individual exhaust pipes 1620, the second collective exhaust pipes 1640, the second cleaning solution supply unit 1660, and the second cleaning solution discharge pipe 1680.

The structure and operation of the plurality of first individual exhaust pipes 1520, the first collective exhaust pipe 1540, the first cleaning solution supply unit 1560, and the first cleaning solution discharge pipe 1580 will be described in detail below.

The first individual exhaust pipe 1520 exhausts gas from the liquid treatment chamber 400 to the gas in the treatment space 402 and/or the gas inside the housing 410.

A damper 1524 is installed inside the first individual exhaust pipe 1520. The damper 1524 may be provided in the shape of a disc. In one exemplary embodiment, the area of the exhaust passage in the first individual exhaust pipe 1520 may be adjusted by rotation of the damper 1524, thereby adjusting the exhaust volume of gas flowing through the first individual exhaust pipe 1520.

Each liquid treatment chamber 400 is connected to the first individual exhaust pipe 1520, and the plurality of first individual exhaust pipes 1520 is connected to the first collective exhaust pipe 1540.

The first collective exhaust pipe 1540 is connected to an outside air inlet 1548. The outside air inlet 1548 may be equipped with an outside air inlet damper 1549 to regulate the amount of outside air introduced into the first collective exhaust pipe 1540. As the process progresses, the number of liquid treatment chambers 400 that are exhausted through the first individual exhaust pipes 1520 changes. The outside air inlet 1548 introduces outside air into the first collective exhaust pipe 1540 such that a constant amount of gas is always exhausted into the first collective exhaust pipe 1540, regardless of the number of first individual exhaust pipe 1520 being exhausted simultaneously. For example, the fewer the number of liquid treatment chambers 400 that are simultaneously exhausted through the first individual exhaust pipe 1520, the greater the amount of outside air introduced into the first collective exhaust pipe 1540 via the outside air inlet 1548.

The first cleaning solution supply unit 1560 is installed in the first collective exhaust pipe 1540. The first cleaning solution supply unit 1560 removes fumes from the gas flowing through the first collective exhaust pipe 1540. The first cleaning solution supply unit 1560 includes a first cleaning nozzle 1564. The first cleaning nozzle 1564 is provided to supply a cleaning solution into the passage of the first collective exhaust pipe 1540. The first cleaning nozzle 1564 may supply the cleaning solution in the form of mist.

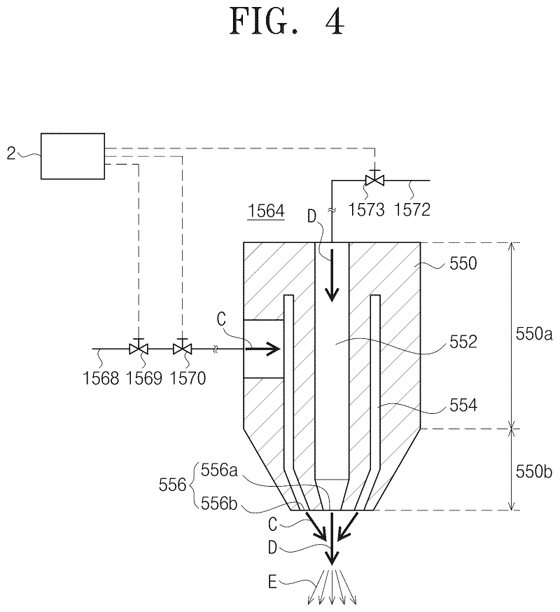

FIG. 4 is a cross-sectional view illustrating one example of the first cleaning nozzle.

Referring to FIG. 4, the first cleaning nozzle 1564 has a body 550. The body 550 has an upper body 550a and a lower body 550b. The upper body 550a may be provided in a cylindrical shape. The lower body 550b extends downwardly from the upper body 550a. The lower body 550b has a shape that narrows in a longitudinal section towards the bottom. The lower body 550b may be provided in a conical shape.

A cleaning solution flow path 552 and a gas flow path 554 are formed in the body 550 The cleaning solution flow path 552 is connected to a cleaning solution supply line 1572. The gas flow path 554 is connected to the gas supply line 1568. The cleaning solution supply line 1572 supplies a cleaning solution from an external cleaning solution supply source to the cleaning solution flow path 552. The cleaning solution may be water. The cleaning solution supply line 1572 is equipped with an open/close valve 1573. The gas supply line 1568 supplies gas to the gas flow path 554 from an external gas supply source. The gas may be nitrogen or air. An open/close valve 1569 and a flow rate regulating valve 1570 are installed in the gas supply line 1568.

The cleaning solution flow path 552 is formed in the center region of the body 550. The cleaning solution flow path 552 may be provided in a straight line from the upper body 550a to the end of the lower body 550b. A liquid outlet 556a of the cleaning solution flow path 552 may be formed at the lower end of the lower body 550b. The gas flow path 554 is formed to surround the cleaning solution flow path 552.

The cleaning solution flow path 552 may be provided in a straight line from the upper body 550a to the end of the lower body 554b. In the upper body 550a region, the gas flow path 554 may be provided parallel to the cleaning solution flow path 552. In the lower body 550b region, the gas flow path 554 may be provided inclined toward the downstream in a direction closer to the liquid outlet 556a of the cleaning solution flow path 552. The gas outlet 556b of the gas flow path 554 is formed to surround the liquid outlet 556a of the cleaning solution flow path 552. With the above structure, the cleaning solution D may be made in the form of mist by the gas pressure when the cleaning solution D and the gas C are simultaneously discharged from the first cleaning nozzle 1564.

From the first collective exhaust pipe 1540, the first cleaning solution discharge pipe 1580 is connected. The first cleaning solution outlet pipe 1580 discharges the cleaning solution and fume discharged from the first cleaning nozzle 1564 from the exhaust passage 1544 of the first collective exhaust pipe 1540. The first cleaning solution discharge pipe 1580 has a discharge pipe portion 1588 and a liquid inlet portion 1584.

The liquid inlet portion 1584 includes an inlet 1592 of the first cleaning solution discharge pipe. The area of the inlet 1592 of the first cleaning solution discharge pipe is provided to be larger than the area of the passage of the discharge pipe portion 1588. The liquid inlet portion 1584 may be provided with a progressively larger cross-sectional area in a direction from the discharge pipe portion 1588 towards the inlet 1592 of the first cleaning solution discharge pipe.

The discharge pipe portion 1588 extends from the liquid inlet portion 1584. The discharge pipe portion 1588 is provided downstream of the liquid inlet portion 1584. The discharge pipe portion 1588 is provided with a constant passage area along its longitudinal direction. The discharge pipe portion 1588 may be provided below the first collective exhaust pipe 1540. Further, the discharge pipe portion 1588 may be disposed parallel to a region downstream of the point at which the first cleaning solution discharge pipe 1580 joins the first collective exhaust pipe 1540. Additionally, the liquid inlet portion 1584 may be positioned to be inclined in a direction that faces upstream of the first collective exhaust pipe 1540 as it moves away from the discharge pipe portion 1588.

The inlet 1592 of the first cleaning solution discharge pipe is provided to be opposed to the first cleaning nozzle 1564. For example, the first cleaning nozzle 1564 may be positioned above the first cleaning solution discharge pipe 1580 and opposed to the first cleaning solution discharge pipe 1580 in an upward and downward direction. Accordingly, the first cleaning nozzle 1564 may dispense a cleaning solution in a direction facing the first cleaning solution discharge pipe 1580.

Referring again to FIG. 3, the exhaust unit 1500 may be controlled by the controller 2. The controller 2 may control the substrate treating apparatus. The controller 2 may include a process controller formed of a microprocessor (computer) that executes the control of the substrate treating apparatus 1, a user interface formed of a keyboard in which an operator performs a command input operation or the like in order to manage the substrate treating apparatus 1, a display for visualizing and displaying an operation situation of the substrate treating apparatus 1, and the like, and a storage unit storing a control program for executing the process executed in the substrate treating apparatus 1 under the control of the process controller or a program, that is, a treating recipe, for executing the process in each component according to various data and treating conditions. Further, the user interface and the storage unit may be connected to the process controller. The treatment recipe may be stored on a memory medium in the memory. The memory medium may be a hard disk. The memory medium may be a portable disk, such as a CD-ROM or a DVD, or a semiconductor memory, such as a flash memory.

Gas in the treatment space 402 generated during treatment of the substrate W in the liquid treatment chamber 400 is discharged from the treatment space 402 by flowing sequentially through the first individual exhaust pipe 1520 and the first collective exhaust pipe 1540.

The first cleaning solution supply unit 1560 supplies a cleaning solution E in the form of mist to the gas B flowing through the exhaust passage 1544 of the first collective exhaust pipe 1540. At the first collective exhaust pipe 1560, the fume A contained in the gas is discharged into the first cleaning solution discharge pipe 1580 along with the cleaning solution.

A damper 1524 installed in the first collective exhaust pipe 1520 controls the opening rate of the first collective exhaust pipe 1520. For example, the controller 2 may control the first individual exhaust pipe 1520 to be open and the second individual exhaust pipe 1620 to be closed so that gas in the treatment space 402 is exhausted into the first individual exhaust pipe 1520 during the process of treating the substrate with the treatment solution of the first component. Furthermore, the controller 2 may control the second individual exhaust pipe 1620 to be open and the first individual exhaust pipe 1520 to be closed so that gas in the treatment space 402 are exhausted into the second individual exhaust pipe 1620 during the process of treating the substrate W with the treatment solution of the second component.

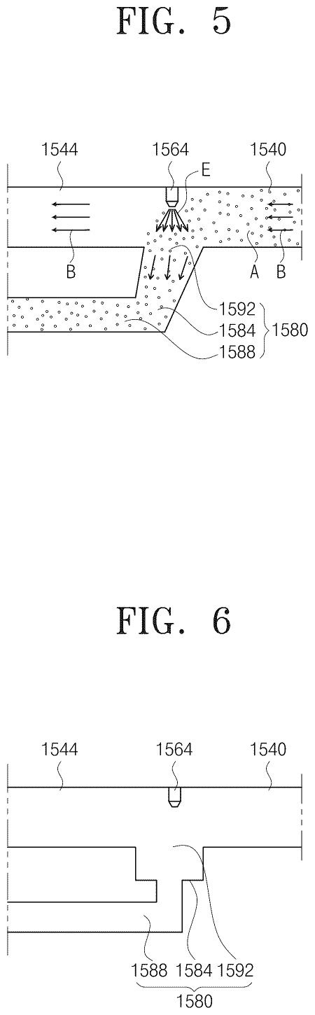

FIG. 5 is a diagram schematically illustrating the flow of fume, gas, and cleaning solution in the first collective exhaust pipe while the gas in the treatment space is exhausted into the first individual exhaust pipe.

Referring to FIG. 5, as the fume A and gas B in the treatment space 402 are exhausted through the exhaust passage 1544 of the first collective exhaust pipe 1540, the first cleaning nozzle 1564 supplies the cleaning solution E in a mist state. As a result, the fume A flowing with gas B from upstream of the first collective exhaust pipe 1540 based on the point where the first cleaning nozzle 1564 is installed is discharged into the first cleaning solution discharge pipe 1580 along with the cleaning solution E, and the gas B from which the fume A has been removed flows downstream of the first collective exhaust pipe 1540.

When the cleaning solution is supplied from the first cleaning nozzle 1564, the size of the mist may be controlled based on the amount of fume contained in the gas being exhausted through the first collective exhaust pipe 1540. When the amount of cleaning solution supplied to the cleaning solution flow path 552 of the first cleaning nozzle 1564 is the same, the size of the mist may be controlled by varying the amount of gas supplied to the gas flow path 554 of the first cleaning nozzle 1564. For example, a larger amount of fume may increase the amount of gas supplied to the gas flow path 554 such that the first cleaning nozzle 1564 supplies a larger amount of a smaller sized mist.

In one example, the first collective exhaust pipe 1540 includes a sensor capable of detecting the amount of fume flowing through the exhaust passage 1544 thereof. The sensor may be installed upstream of the point where the first cleaning solution nozzle 1564 is installed. In one exemplary embodiment, the sensor may detect the amount of fume by measuring pressure in the first collective exhaust pipe 1540. When the pressure in the first collective exhaust pipe 1540 increases to a first set pressure or greater, the controller 2 determines that the amount of fume has increased, and the controller 2 controls the cleaning solution supplied through the first cleaning nozzle 1564 to become more atomized. Subsequently, when the pressure in the first collective exhaust pipe 1540 decreases to a second set pressure or below, the controller 2 determines that the amount of fume has decreased and reduces the amount of gas C supply.

Optionally, the controller 2 controls the mist size of the cleaning solution based on the type of treatment solution supplied to the substrate W within the treatment space 402. For example, the case where the first treatment solution generates a greater amount of fume when treating the substrate compared to the second treatment solution will be described. The first treatment solution and the second treatment solution may be both acidic components or both basic components. Optionally, one of the first treatment solution and the second treatment solution may be an acidic component and the other may be a basic component. In this case, the amount of gas supplied to the first cleaning nozzle 1564 during treatment of the substrate using the first treatment solution is greater than the amount of gas supplied to the first cleaning nozzle 1564 during the treatment of the substrate using the second treatment solution. Thus, the mist of cleaning solution when the fume of the first treatment solution flows along the exhaust passage 1544 of the first collective exhaust pipe 1540 is of a smaller size than the mist of cleaning solution when the fume of the second treatment solution flows along the passage of the first collective exhaust pipe 1540, and a larger volume is discharged.

Optionally, as the number of liquid treatment chambers 400 that are simultaneously exhausting through the first collective exhaust pipe 1540 is greater, the controller 2 may control the first cleaning solution nozzle 1564 to supply a smaller sized mist of cleaning solution.

The controller 2 may control the first cleaning solution supply unit 1560 to cause the first cleaning nozzle 1564 to supply a cleaning solution at all times while the gas in the liquid treatment chamber 400 is being exhausted through the first collective exhaust pipe 1540.

Optionally, the controller 2 may control the first cleaning solution supply unit 1560 to discharge a cleaning solution from the first cleaning nozzle 1564 at a set interval.

Optionally, the controller 2 may control the first cleaning solution supply unit 1560 to cause the first cleaning solution to be discharged from the first cleaning nozzle 1564 when an interlock occurs in the substrate treating apparatus 1 due to an abnormality in the exhaust unit 1500.

In the exemplary embodiment of FIG. 3, the inlet 1592 of the first cleaning solution discharge pipe was described as having a gradually increasing area from the discharge pipe portion 1588 towards the inlet 1592 of the first cleaning solution discharge pipe. Alternatively, however, the liquid inlet portion 1584 may be provided to be stepped, as illustrated in FIG. 6.

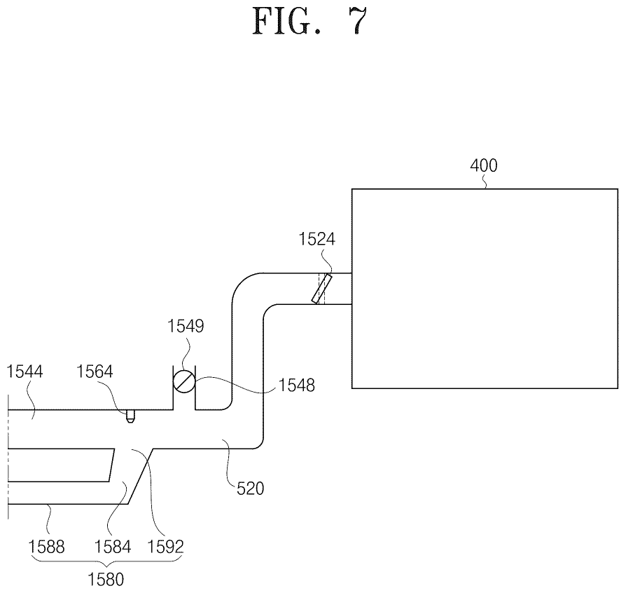

In FIG. 3, the cleaning nozzle 1564 and the cleaning solution discharge pipe 1580 are described as being installed in the collective exhaust pipe 1540 in a structure in which the individual exhaust pipes 1520 each connected to the plurality of liquid treatment chambers 400 are connected to the collective exhaust pipe 1540. However, as illustrated in FIG. 7, the cleaning nozzle 1564 and the cleaning solution discharge pipe 1580 may be installed in the exhaust pipe 520 directly connected to a single liquid treatment chamber 400.

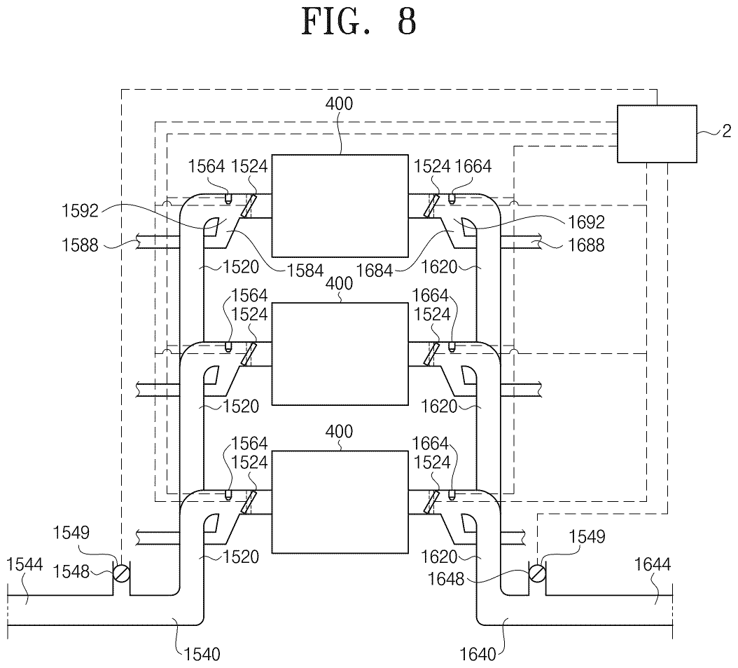

In FIG. 3, it has been described as in the structure in which the first individual exhaust pipes 1520 and the second individual exhaust pipes 1620 are connected to the first collective exhaust pipe 1540 and the second collective exhaust pipe 1640 connected to the plurality of liquid treatment chambers 400, respectively, the first cleaning nozzle 1564 and the first cleaning solution discharge pipe 1580 are installed in the first collective exhaust pipe 1540, and the cleaning nozzle 1564 and the second cleaning solution discharge pipe 1680 are installed in the second collective exhaust pipe 1640. However, as illustrated in FIG. 8, the first cleaning nozzle 1564 and the first cleaning solution discharge pipe 1580 may be installed in the first individual exhaust pipe 1520 and the second individual exhaust pipe 1620, respectively.

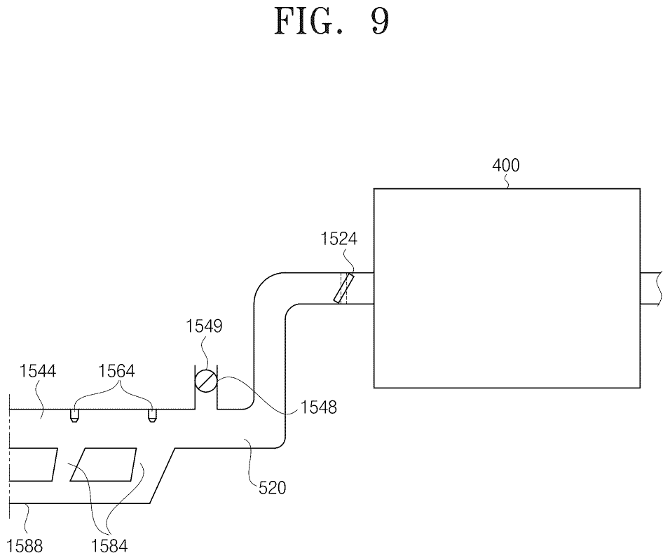

In the example described above, the single first cleaning nozzle 1564 is described as being provided in the first collective exhaust pipe 1540. However, contrary to this, a plurality of first cleaning nozzles 1564 may be provided within the first collective exhaust pipe 1540. For example, as illustrated in FIG. 9, the plurality of first cleaning nozzles 1564 may be spaced apart from one another along the longitudinal direction of the first collective exhaust pipe 1540. In this case, the cleaning solution discharge pipe 1580 may have a plurality of liquid inlet portions 1584, each of the liquid inlet portions 1584 may be provided at a position opposite the respective first cleaning nozzle 1564.

In the examples described above, where two collective exhaust pipes 1540 and 1640 are provided, the cleaning nozzles 1564 and 1664 and the cleaning solution discharge pipes 1580 are 1680 are described as being installed in the collective exhaust pipes 1520 and 1620, respectively. Alternatively, however, the cleaning nozzle 1564 and the cleaning solution outlet pipe 1580 may be installed in only one collective exhaust pipe 1540 of the plurality of collective exhaust pipes 1540 and 1640.

What is claimed is:

1. An apparatus for treating a substrate, the apparatus comprising:
a liquid treatment chamber having a treatment space and supplying a treatment solution to a substrate disposed in the treatment space to liquid treat the substrate; and
an exhaust unit for exhausting gas in the treatment space,
wherein the exhaust unit includes:
an exhaust pipe connected to the liquid treatment chamber, and having a first exhaust passage through which gas exhausted from the treatment space flows;
a first cleaning solution supply unit provided in the exhaust pipe to supply a cleaning solution to the gas flowing through the first exhaust passage; and
a first cleaning solution discharge pipe connected to the exhaust pipe to discharge the cleaning solution supplied to the first exhaust passage.

2. The apparatus of claim 1, wherein the first cleaning solution supply unit includes a first cleaning nozzle that sprays a cleaning solution.

3. The apparatus of claim 2, wherein the first cleaning nozzle is provided to spray a cleaning solution in a direction towards the first cleaning solution discharge pipe.

4. The apparatus of claim 3, wherein an inlet of the first cleaning solution discharge pipe and the first cleaning nozzle are provided to be opposed to each other in an upward and downward direction.

5. The apparatus of claim 2, wherein the first cleaning nozzle is provided to spray a cleaning solution in the form of mist.

6. The apparatus of claim 5, wherein the first cleaning nozzle further includes: a body;
a cleaning solution flow path provided in the body and discharging a cleaning solution; and
a gas flow path formed in the body, and supplying gas towards the cleaning solution discharged from the cleaning solution flow path to make the cleaning solution be in the form of mist.

7. The apparatus of claim 2, wherein the first cleaning solution supply unit further includes a controller controlling the first cleaning nozzle, and
the controller controls the first cleaning solution supply unit to cause the first cleaning nozzle to discharge a cleaning solution at a set interval.

8. The apparatus of claim 2, wherein the first cleaning solution supply unit further includes a controller controlling the first cleaning nozzle, and
the controller controls the cleaning solution supply unit to cause the first cleaning nozzle to spray a cleaning solution when an interlock occurs in the substrate treating apparatus due to an abnormality in the exhaust unit.

9. The apparatus of claim 6, wherein the first cleaning solution supply unit further includes a controller controlling the first cleaning nozzle, and
the controller controls the first cleaning solution supply unit such that the amount of discharge of the gas is varied based on the amount of fume contained in the gas being exhausted through the first exhaust passage.

10. The apparatus of claim 9, wherein the controller controls the first cleaning solution supply unit such that when the amount of fume contained in the exhausted gas increases, the amount of gas supplied to the first cleaning nozzle is increased.

11. The apparatus of claim 1, wherein the first cleaning solution discharge pipe includes:
a liquid inlet portion including an inlet of the first cleaning solution discharge pipe; and
a discharge pipe portion extending from an end of the liquid inlet portion and having a passage area constant along a longitudinal direction thereof, and
an area of the inlet of the first cleaning solution discharge pipe is provided to be larger than an area of a passage of the discharge pipe portion.

12. The apparatus of claim 11, wherein the liquid inlet portion is provided to have a cross-sectional area gradually increasing from the discharge pipe portion in a direction towards the inlet of the first cleaning solution discharge pipe.

13. The apparatus of claim 11, wherein the discharge pipe portion is disposed below the exhaust pipe and parallel to the exhaust pipe, and
the liquid inlet portion is inclined upwardly from an end of the discharge pipe portion in an opposite direction of the exhaust pipe portion and connected to the exhaust pipe.

14. An apparatus for treating a substrate, the apparatus comprising:
a plurality of liquid treatment chambers having a treatment space, and supplying a treatment solution to a substrate located in the treatment space to liquid treat the substrate; and
an exhaust unit for exhausting gas from the treatment space of each of the plurality of liquid treatment chambers,
wherein the exhaust unit includes:
a plurality of first individual exhaust pipes connected to the plurality of corresponding liquid treatment chambers, respectively;
a first collective exhaust pipe to which the plurality of first individual exhaust pipes is connected and through which gas exhausted through each of the plurality of first individual exhaust pipes flows;
a first cleaning solution supply unit provided in the first collective exhaust pipe to supply a cleaning solution to the gas flowing through the first collective exhaust pipe; and
a first cleaning solution discharge pipe connected to the first collective exhaust pipe to discharge a cleaning solution supplied to the first collective exhaust pipe.

15. The apparatus of claim 14, wherein each of the plurality of liquid treatment chambers includes:
a first nozzle for supplying a treatment solution of a first component; and
a second nozzle for supplying a treatment solution of a second component, and
the exhaust unit includes:
a plurality of second individual exhaust pipes connected to the plurality of corresponding liquid treatment chambers, respectively;
a second collective exhaust pipe to which the plurality of second individual exhaust pipes is connected and through which gas exhausted through each of the plurality of secondary individual exhaust pipes flows;
a second cleaning solution supply unit provided in the second collective exhaust pipe to supply a cleaning solution to the gas flowing through the second collective exhaust pipe; and
a second cleaning solution discharge pipe connected to the second collective exhaust pipe to discharge a cleaning solution supplied to the second collective exhaust pipe.

16. The apparatus of claim 14, wherein the first cleaning solution supply unit includes a first cleaning nozzle for spraying a cleaning solution to gas flowing through the first collective exhaust pipe, and
the first cleaning nozzle is provided to spray a cleaning solution in a direction towards the first cleaning solution discharge pipe.

17. The apparatus of claim 16, wherein an inlet of the first cleaning solution discharge pipe and the first cleaning nozzle are provided to be opposed to each other in an upward and downward direction.

18. The apparatus of claim 16, wherein the first cleaning nozzle and the second cleaning nozzle are provided to spray a cleaning solution in the form of mist, and
the first cleaning nozzle further includes:
a body;
a cleaning solution flow path provided in the body and discharging a cleaning solution; and
a gas flow path for supplying gas toward the cleaning solution discharged from the cleaning solution flow path to make the cleaning solution be in the form of mist.

19. The apparatus of claim 14, wherein the first cleaning solution discharge pipe includes:
a liquid inlet portion including an inlet of the first cleaning solution discharge pipe; and
a discharge pipe portion extending from the liquid inlet portion and having a passage area constant along a longitudinal direction thereof,
an area of the inlet of the first cleaning solution discharge pipe is provided larger than an area of a passage of the discharge pipe portion, and
the liquid inlet portion is provided to have a cross-sectional area gradually expanding from the discharge pipe portion in a direction toward the inlet of the first cleaning solution discharge pipe.

20. An apparatus for treating a substrate, the apparatus comprising:
a plurality of liquid treatment chambers having a treatment space and supplying a treatment solution to a substrate located in the treatment space to liquid treat the substrate; and
an exhaust unit for exhausting gas from the treatment space of each of the plurality of liquid treatment chambers,
each of the plurality of liquid treatment chambers includes:
a first nozzle for supplying a treatment solution of a first component; and
a second nozzle for supplying a treatment solution of a second component, and
the exhaust unit includes:
a plurality of first individual exhaust pipes connected to the plurality of corresponding liquid treatment chambers, respectively;
a plurality of second individual exhaust pipes connected to the liquid treatment chambers, respectively, at a position facing the plurality of first individual exhaust pipes when viewed from the top;
a first collective exhaust pipe to which the plurality of first individual exhaust pipes is connected and through which gas exhausted through each of the plurality of first individual exhaust pipes flows;
a second collective exhaust pipe to which the plurality of second individual exhaust pipes is connected and through which gas exhausted through each of the plurality of secondary individual exhaust pipes flows;
a first cleaning solution supply unit provided in the first collective exhaust pipe to supply a cleaning solution to the gas flowing through the first collective exhaust pipe; and
a first cleaning solution discharge pipe connected to the first collective exhaust pipe to discharge the cleaning solution supplied to the first collective exhaust pipe,
the first cleaning solution supply unit includes a first cleaning nozzle for spraying a cleaning solution to gas flowing through the first collective exhaust pipe in the form of mist,
an inlet of the first cleaning solution discharge pipe and the first cleaning nozzle are provided to face each other in an upward and downward direction,
the first cleaning solution discharge pipe includes:
a liquid inlet portion including an inlet of the first cleaning solution discharge pipe; and
a discharge pipe portion extending from the liquid inlet portion and having a passage area constant along a longitudinal direction thereof, and
an area of the inlet of the first cleaning solution discharge pipe is provided larger than the passage area of the discharge pipe portion.
